(19) United States
(12) Patent Application Publication
(10) Pub. No.: US 2025/0096111 A1
(43) Pub. Date: Mar. 20, 2025

(54) PACKAGE COMPRISING A SUBSTRATE WITH A PASSIVE COMPONENT BLOCK

(71) Applicant: QUALCOMM Incorporated, San Diego, CA (US)

(72) Inventors: Michelle Yejin KIM, Carlsbad, CA (US); Hong Bok WE, San Diego, CA (US); Joan Rey Villarba BUOT, Escondido, CA (US); Kuiwon KANG, San Diego, CA (US)

(21) Appl. No.: 18/467,163

(22) Filed: Sep. 14, 2023

(51) Int. Cl. H01L 23/522; H01L 23/00; H01L 23/498; H01L 23/538; H01L 25/065

(52) U.S. Cl. CPC H01L 23/5223; H01L 23/49822; H01L 23/5389; H01L 24/05; H01L 24/13; H01L 25/0657; H01L 2224/05014; H01L 2224/05025; H01L 2224/13025; H01L 2224/13028; H01L 2924/1205; H01L 2924/1811

(57) ABSTRACT

A package comprising an integrated device; and a substrate coupled to the integrated device through at least a plurality of solder interconnects. The substrate comprises a core layer comprising a cavity; a region comprising a passive component block located at least partially in the cavity of the core layer, wherein the passive component block comprises a first passive device and a second passive device; at least one dielectric layer coupled to the core layer; and a plurality of interconnects located at least partially in the at least one dielectric layer.

### FIELD

Various features relate to packages and substrates.

### BACKGROUND

Packages can include a substrate, an integrated device and passive devices. The substrate may include a plurality of interconnects. Passive devices help in the proper operation of the package and any integrated devices that may be electrically coupled to passive devices. There is an ongoing need to provide smaller packages with improved performances, such as packages with improved passive device performance and/or passive devices with reliable and robust joint connections in the package.

### SUMMARY

Various features relate to packages and substrates.

One example provides a substrate comprising a core layer comprising a cavity; a region comprising a passive component block located at least partially in the cavity of the core layer, at least one dielectric layer coupled to the core layer; and a plurality of interconnects located at least partially in the at least one dielectric layer. The passive component block comprises a first passive device and a second passive device.

Another example provides a package comprising an integrated device; and a substrate coupled to the integrated device through at least a plurality of solder interconnects. The substrate comprises a core layer comprising a cavity; a region comprising a passive component block located at least partially in the cavity of the core layer, wherein the passive component block comprises a first passive device and a second passive device; at least one dielectric layer coupled to the core layer; and a plurality of interconnects located at least partially in the at least one dielectric layer.

Another example provides a method for fabricating a substrate. The method provides a core layer. The method forms a cavity in the core layer. The method provides a passive component block in the cavity of the core layer, where the passive component block includes a first passive device and a second passive device. The method forms at least one dielectric layer coupled to (i) the core layer and (ii) the passive component block. The method forms a plurality of interconnects located at least partially in the at least one dielectric layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary profile view of a substrate with a passive component block.

FIG. 2 illustrates a close up view of an exemplary profile view of a passive component block in a substrate.

FIG. 3 illustrates an exemplary profile view of a substrate with a passive component block.

FIG. 4 illustrates a close up view of an exemplary profile view of a passive component block in a substrate.

FIG. 5 illustrates an exemplary profile view of a passive component block.

FIGS. 6A-6C illustrate an exemplary sequence for fabricating a passive component block.

FIG. 7 illustrates an exemplary sequence for fabricating a passive component block.

FIGS. 8A-8H illustrate an exemplary sequence for fabricating a substrate with a passive component block.

FIG. 9 illustrates an exemplary sequence for fabricating a substrate with a passive component block.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device; and a substrate coupled to the integrated device through at least a plurality of solder interconnects. The substrate comprises a core layer comprising a cavity; a region comprising a passive component block located at least partially in the cavity of the core layer, wherein the passive component block comprises a first passive device and a second passive device; at least one dielectric layer coupled to the core layer; and a plurality of interconnects located at least partially in the at least one dielectric layer. In some implementations, the first passive device may include a first deep trench capacitor and the second passive device may include a second deep trench capacitor.

### Exemplary Package With a Substrate Comprising a Passive Component Block

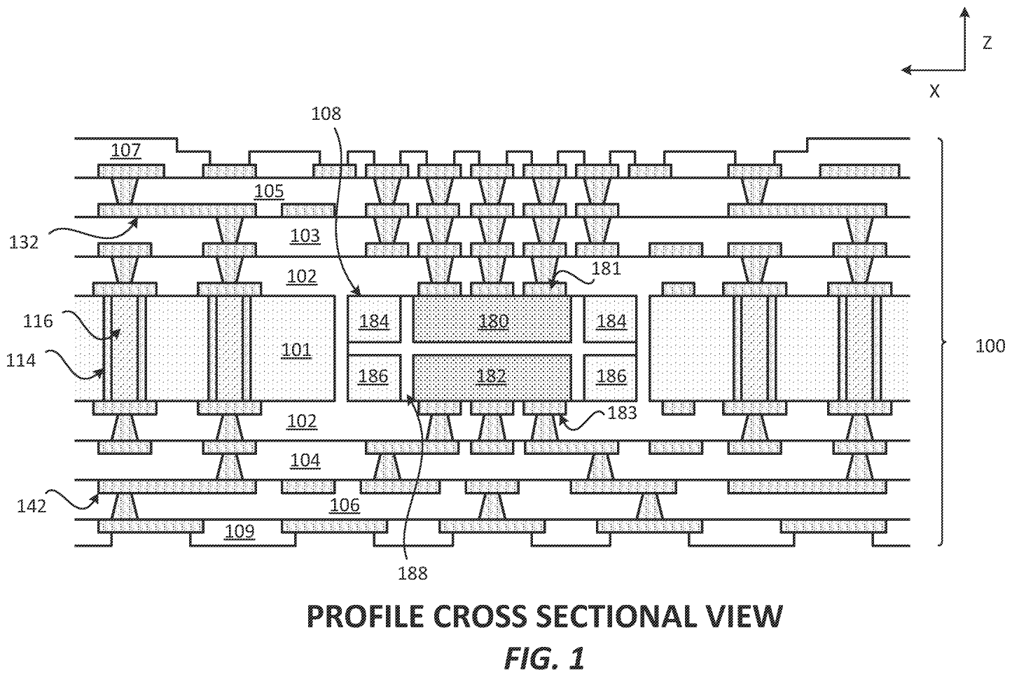

FIG. 1 illustrates a profile view of a substrate 100 that includes a passive component block. The substrate 100 may be part of a package that includes an integrated device. The substrate 100 includes a core layer 101, a dielectric layer 102, a dielectric layer 103, a dielectric layer 104, a dielectric layer 105, a dielectric layer 106, a solder resist layer 107, a solder resist layer 109, a passive component block 108, plurality of via interconnects 114, a plurality of fills 116, a plurality of interconnects 132 and a plurality of interconnects 142. The passive component block 108 may include a silicon capacitor, a deep trench capacitor (DTC) and/or a deep trench capacitor (DTC) device. A silicon capacitor may be a capacitor that is formed on a silicon substrate. As will be further described below, the passive component block 108 may include at least two passive devices. As will be further described below, the passive component block 108 may be an embedded passive component block that is at least partially embedded and/or at least partially located in the substrate 100. The passive component block 108 and/or components of the passive component block 108 may be located in a region (e.g., passive component region) of the substrate 100.

The core layer 101 includes a cavity that is at least partially filled and/or at least partially occupied by the passive component block 108 and the dielectric layer 102. The core layer 101 may laterally surround the passive component block 108. The passive component block 108 includes a passive device 180, a passive device 182, a block core layer 184, a block core layer 186 and a dielectric layer 188. The dielectric layer 188 is coupled to and touching the passive device 180, the passive device 182, the block core layer 184 and/or the block core layer 186. In some implementations, the passive device 180 may be a first passive device and the passive device 182 may be a second passive device. In some implementations, the block core layer 184 may be a first block core layer and the block core layer 186 may be a second core block layer.

The passive device 180 may include a plurality of pad interconnects 181 (e.g., first plurality of pad interconnects, first plurality of passive device pad interconnects). The passive device 182 may include a plurality of pad interconnects 183 (e.g., second plurality of pad interconnects, second plurality of passive device pad interconnects). The passive device 180 may include a front side and a back side. The front side of the passive device 180 may be the side that includes the plurality of pad interconnects 181. The back side of the passive device 180 may be opposite to the front side of the passive device 180. The passive device 182 may include a front side and a back side. The front side of the passive device 182 may be the side that includes the plurality of pad interconnects 181. The back side of the passive device 182 may be opposite to the front side of the passive device 182. The passive device 180 and the passive device 182 are at least partially located in the passive component block 108 such that the back side of the passive device 180 faces the back side of the passive device 182. The dielectric layer 188 may be located between the passive device 180 and the passive device 182. The dielectric layer 188 may be located between the passive device 180 and the block core layer 184. The dielectric layer 188 may be located between the passive device 182 and the block core layer 186. The dielectric layer 188 may include a different material from the block core layer 184 and/or the block core layer 186.

The plurality of via interconnects 114 extend through the core layer 101. The plurality of fills 116 may be located within the plurality of via interconnects 114. The dielectric layer 102 is coupled to a first surface (e.g., top surface) of the core layer 101 and a second surface (e.g., bottom surface) of the core layer 101. The dielectric layer 102 may include a different material from the core layer 101.

The dielectric layer 103 is coupled to the dielectric layer 102. The dielectric layer 105 is coupled to the dielectric layer 103. The plurality of interconnects 132 are located at least partially in the dielectric layer 102, the dielectric layer 103 and/or the dielectric layer 105. The plurality of interconnects 132 are coupled to the plurality of via interconnects 114. The solder resist layer 107 is coupled to the dielectric layer 105.

The dielectric layer 104 is coupled to the dielectric layer 102. The dielectric layer 106 is coupled to the dielectric layer 104. The plurality of interconnects 142 are located at least partially in the dielectric layer 102, the dielectric layer 104 and/or the dielectric layer 106. The plurality of interconnects 142 are coupled to the plurality of via interconnects 114. The solder resist layer 109 is coupled to the dielectric layer 106.

In some implementations, the dielectric layer 102, the dielectric layer 103, the dielectric layer 104, the dielectric layer 105, and/or the dielectric layer 106 may include prepreg and/or Ajinomoto Build-up Film (ABF). However, the dielectric layer 102, the dielectric layer 103, the dielectric layer 104, the dielectric layer 105, and/or the dielectric layer 106 may be a different type of dielectric. The solder resist layer 107 is coupled to a surface of the dielectric layer 105. The solder resist layer 109 is coupled to a surface of the dielectric layer 106. The core layer 101 may be a type of a dielectric. The core layer 101 may include a different material and/or a same material as the dielectric layer 102. In some implementations, the dielectric layer 102, the dielectric layer 103, the dielectric layer 104, the dielectric layer 105, and/or the dielectric layer 106 may be considered as one dielectric layer.

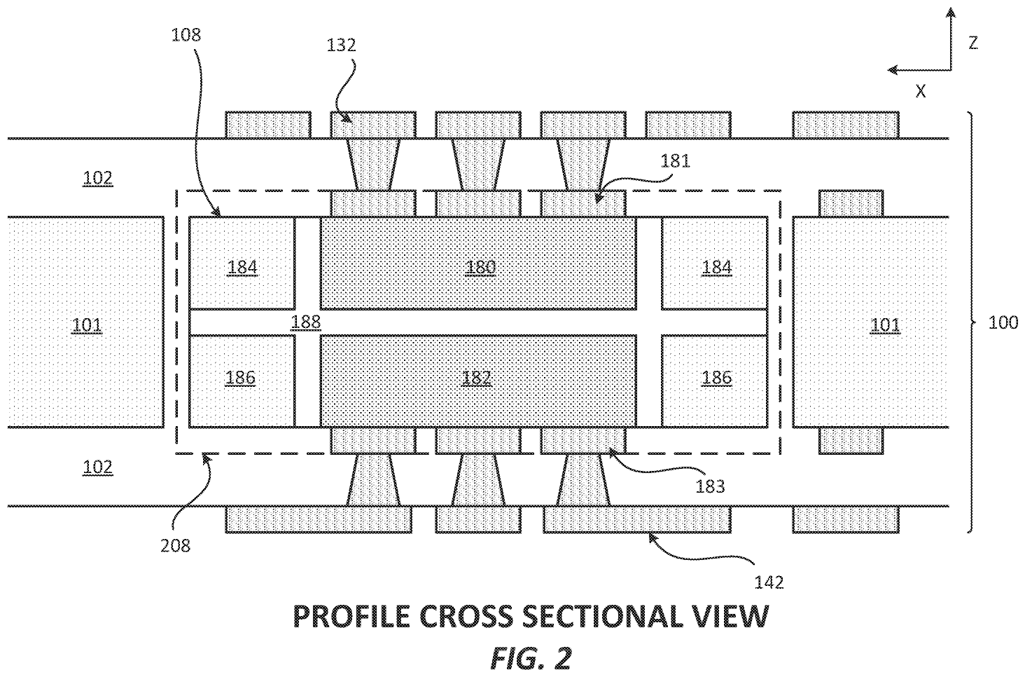

FIG. 2 illustrates a close up view of a passive component block 108 located in the substrate 100. As shown in FIG. 2, the substrate 100 includes a region 208. The region 208 may be a passive component region. The region 208 may include the passive component block 108 and/or one or more components of the passive component block 108. The region 208 may include a cavity of the core layer 101 and/or portions of the dielectric layer 102 located in the cavity of the core layer 101. The passive component block 108 is at least partially surrounded by the dielectric layer 102 and/or the core layer 101. The passive component block 108 is located in a cavity of the core layer 101. Part of the cavity of the core layer 101 may be at least partially filled with the dielectric layer 102. The dielectric layer 102 may touch several surfaces of the passive component block 108. The passive component block 108 may include the plurality of pad interconnects 181 and the plurality of pad interconnects 183. A plurality of via interconnects from the plurality of interconnects 132 may be coupled to and touching the plurality of pad interconnects 181. The plurality of pad interconnects 181 may be pad interconnects for the passive device 180. A plurality of via interconnects from the plurality of interconnects 142 may be coupled to and touching the plurality of pad interconnects 183. The plurality of pad interconnects 183 may be pad interconnects for the passive device 182.

In some implementations, the dielectric layer 188 may be considered part of the dielectric layer 102. This may be the case, when the dielectric layer 188 and the dielectric layer 102 include the same material. In some implementations, the dielectric layer 188 of the passive component block 108 may not be distinguishable from the dielectric layer 102 of the substrate 100. For example, there may not be a boundary interface between the dielectric layer 188 and the dielectric layer 102. Thus, in one example, the dielectric layer 102 of the substrate 100 may look like it is located (i) between the passive device 180 and the passive device 182, (ii) between the passive device 180 and the block core layer 184, and/or (iii) between the passive device 182 and the block core layer 186. Thus, in some implementations, the dielectric layer 188 and/or part of the dielectric layer 102 may be considered to be part of the passive component block 108. In some implementations, the passive component block 108 may be a structure and/or structural configuration that includes the passive device 180, the passive device 182, the block core layer 184 and the block core layer 186, where the dielectric layer 188 may be a dielectric layer that is considered part of the substrate 100. In one example, the substrate 100 may include the passive device 180, the passive device 182, the block core layer 184 and the block core layer 186 that are located in the substrate 100. The passive device 180 may be laterally surrounded by the block core layer 184. The passive device 182 may be laterally surrounded by the block core layer 186. The passive device 180, the passive device 182, the block core layer 184 and the block core layer 186 may surrounded by the dielectric layer 102. The passive device 180 may have a front side and a back side. The passive device 182 may have a front side and a back side. The passive device 180 and the passive device 182 are located in the substrate 100 such that the back side of the passive device 180 faces the back side of the passive device 182. The passive device 180, the passive device 182, the block core layer 184 and the block core layer 186 may be located at least partially in a cavity of the core layer 101, where the cavity is at least partially filled with the dielectric layer 102. In some implementations, the passive device 180, the passive device 182, the block core layer 184 and the block core layer 186 do not directly touch the core layer 101. In some implementations, the dielectric layer 188 may be considered separate from the dielectric layer 102 (e.g., for example, there may be a boundary interface between the dielectric layer 188 and the dielectric layer 102). The dielectric layer 188 may include the same material or a different material from the dielectric layer 102. The block core layer 184 may laterally surround the passive device 180. The block core layer 186 may laterally surround the passive device 182. The block core layer 184, the block core layer 186 may include the same material as the core layer 101. A passive component block as used in the disclosure may mean to represent one or more components, a structure and/or a structural configuration of various components.

In some implementations, the region 208 of the substrate 100, may include the passive device 180, the passive device 182, the block core layer 184 and the block core layer 186. In some implementations, the region 208 may also include a portion of the dielectric layer 102 and/or the dielectric layer 188. The passive device 180 may be laterally surrounded by the block core layer 184. The passive device 182 may be laterally surrounded by the block core layer 186. The passive device 180, the passive device 182, the block core layer 184 and the block core layer 186 may surrounded by the dielectric layer 102. The passive device 180 may have a front side and a back side. The passive device 182 may have a front side and a back side. The passive device 180 and the passive device 182 are located in the substrate 100 such that the back side of the passive device 180 faces the back side of the passive device 182. The passive device 180, the passive device 182, the block core layer 184 and the block core layer 186 may be located at least partially in a cavity of the core layer 101, where the cavity is at least partially filled with the dielectric layer 102. The passive device 180 and the passive device 182 may be approximately the same size and/or shape, or they can be different sizes and/or shapes. The passive device 180 and the passive device 182 may vertically overlap (e.g., complete vertical overlap or partial vertical overlap).

The passive component block 108 and/or the passive component region (e.g., region 208) of the substrate provide several benefits and/or advantages. One, the passive component block 108 may not be subject to process limitations of thicker passive devices, due to the use of thinner dual core passive devices. Two, providing two or more passive devices may eliminate the need for land side passive devices that are coupled to a bottom side of the substrate, which may further eliminate the need to depopulate solder interconnects on the land side of the substrate. Three, the passive component block 108 may have better adhesion to a tape when the dielectric layer 102 is provided, which means that the passive component block 108 is less likely to move and/or shift when the dielectric layer 102 is provided. This may result in a more reliable and robust connection of interconnects between the substrate and the passive component block 108. Four, the passive component block 108 provides a fairly symmetrical structure in the substrate, which may help with providing a balanced substrate.

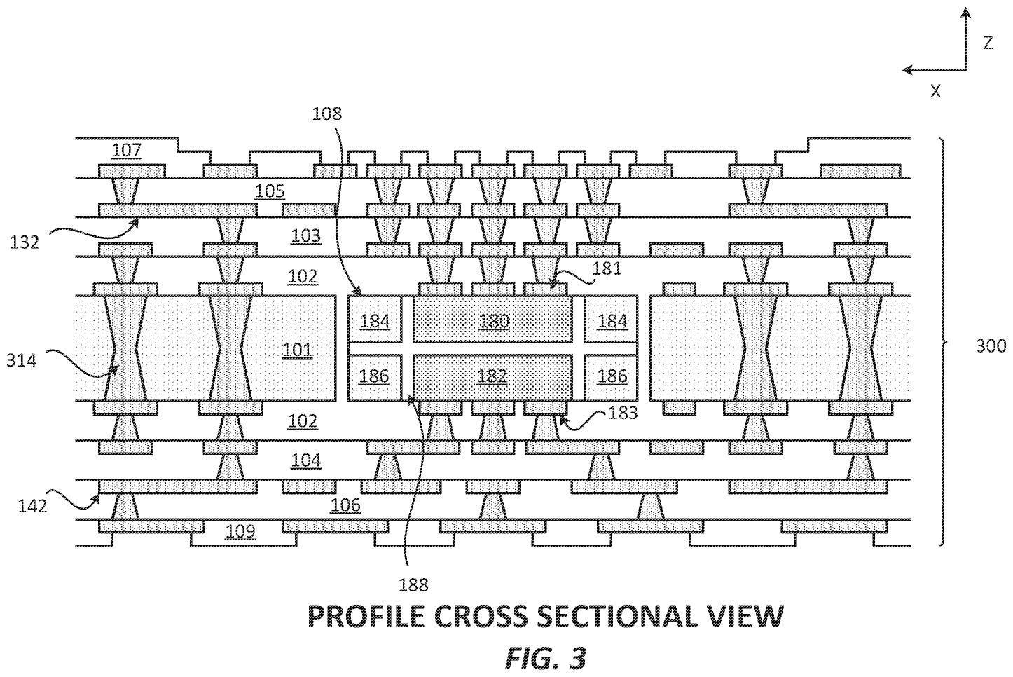

FIG. 3 illustrates a profile view of a substrate 300 that includes a passive component block. The substrate 300 may be part of a package that includes an integrated device. The substrate 300 is similar to the substrate 100, and thus includes similar components as the substrate 100.

The substrate 300 includes a core layer 101, a dielectric layer 102, a dielectric layer 103, a dielectric layer 104, a dielectric layer 105, a dielectric layer 106, a solder resist layer 107, a solder resist layer 109, a passive component block 108, a plurality of via interconnects 314, a plurality of interconnects 132 and a plurality of interconnects 142. The substrate 300 may include the plurality of via interconnects 314 that extend through the core layer 101, instead of the plurality of via interconnects 114 and the plurality of fills 116, that are described and illustrated in FIG. 1.

The shape of the plurality of via interconnects 314 is different to the shape of the plurality of via interconnects 114. The plurality of via interconnects 314 are coupled to the plurality of interconnects 132 and/or the plurality of interconnects 142. The passive component block 108 is embedded and/or located in the substrate 300 in a similar manner, as described for the substrate 100. The passive component block 108 is configured to be coupled to the plurality of interconnects 132 and/or the plurality of interconnects 142 of the substrate 300, in a similar manner as described to the plurality of interconnects 132 and/or the plurality of interconnects 142 of the substrate 100.

It is noted that a substrate (e.g., 100, 300) may include more than one passive component block 108. The passive component block 108 may have different sizes, shapes, and/or thicknesses. In some implementations, the passive component block 108 may be symmetrical or approximately symmetrical about a center horizontal line across the passive component block 108. In some implementations, a passive component block 108 may include more than two passive devices. For example, a passive component block 108 may include two or more upper passive devices and two or more bottom passive devices.

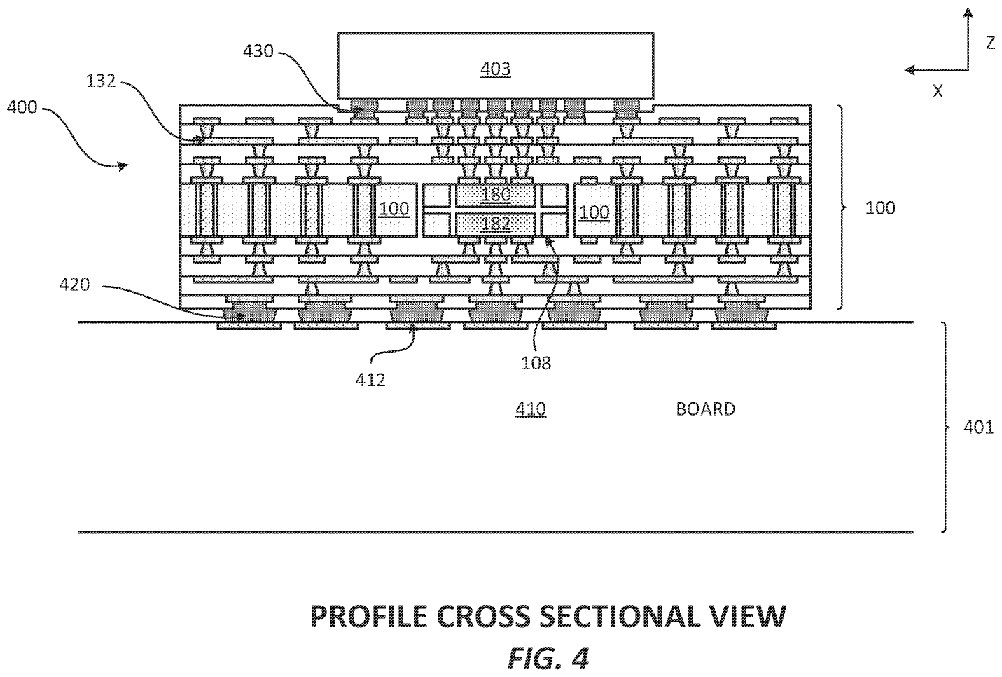

FIG. 4 illustrates a package 400 that includes a substrate 100 and an integrated device 403. The package 400 is coupled to a board 401 through a plurality of solder interconnects 420. The board 401 includes at least one board dielectric layer 410 and a plurality of board interconnects 412. The integrated device 403 is coupled to the substrate 100 through at least a plurality of solder interconnects 430. In some implementations, the integrated device 403 may be coupled to the substrate 100 through the plurality of solder interconnects 430 and/or a plurality of pillar interconnects (not shown). The plurality of solder interconnects 430 and/or the plurality of pillar interconnects may be referred as a plurality of bump interconnects.

As mentioned above, the substrate 100 includes a passive component block 108. The integrated device 403 may be configured to be electrically coupled to the passive component block 108 located in the substrate 100. In some implementations, at least one electrical path between (i) the integrated device 403 and (ii) the passive device 180 of the passive component block 108, may include (i) at least one solder interconnect from the plurality of solder interconnects 430, (ii) some interconnects from the plurality of interconnects 132 and (iii) at least one pad interconnect from the plurality of pad interconnects 181.

In some implementations, at least one electrical path between (i) the integrated device 403 and (ii) the passive device 182 of the passive component block 108, may include (i) at least one solder interconnect from the plurality of solder interconnects 430, (ii) some interconnects from the plurality of interconnects 132, (iii) at least one via interconnect from the plurality of via interconnects 114, (iv) some interconnects from the plurality of interconnects 142, and (v) at least one pad interconnect from the plurality of pad interconnects 183.

The integrated device 403 may be configured to be electrically coupled to the board 401 through (i) solder interconnects from the plurality of solder interconnects 430, (ii) interconnects from the plurality of interconnects from the substrate 100 (which may include the plurality of interconnects 132, the plurality of via interconnects 114, and/or the plurality of interconnects 142), and (iii) solder interconnects from the plurality of solder interconnects 420.

In some implementations, instead of the substrate 100, the substrate 300 may be implemented in the package 400. In such instances, the integrated device 403 may be coupled to the substrate 300 through the plurality of solder interconnects 430 and/or a plurality of pillar interconnects (not shown). The integrated device 403 may be configured to be electrically coupled to the passive component block 108 located in the substrate 300.

In some implementations, at least one electrical path between (i) the integrated device 403 and (ii) the passive device 180 of the passive component block 108, may include (i) at least one solder interconnect from the plurality of solder interconnects 430, (ii) some interconnects from the plurality of interconnects 132 and (iii) at least one pad interconnect from the plurality of pad interconnects 181.

In some implementations, at least one electrical path between (i) the integrated device 403 and (ii) the passive device 182 of the passive component block 108, may include (i) at least one solder interconnect from the plurality of solder interconnects 430, (ii) some interconnects from the plurality of interconnects 132, (iii) at least one via interconnect from the plurality of via interconnects 314, (iv) some interconnects from the plurality of interconnects 142, and (v) at least one pad interconnect from the plurality of pad interconnects 183.

The integrated device 403 may be configured to be electrically coupled to the board 401 through (i) solder interconnects from the plurality of solder interconnects 430, (ii) interconnects from the plurality of interconnects from the substrate 300 (which may include the plurality of interconnects 132, the plurality of via interconnects 314, and/or the plurality of interconnects 142), and (iii) solder interconnects from the plurality of solder interconnects 420.

### Exemplary Passive Device

Different implementations may provide different types of passive devices in a passive component block. In some implementations, the passive device (e.g., 180, 182) includes an integrated passive device (IPD). In some implementations, the passive device (e.g., 180, 182) includes a deep trench capacitor (e.g., trench capacitor device). In some implementations, the passive device (e.g., 180, 182) is implemented as a passive chiplet.

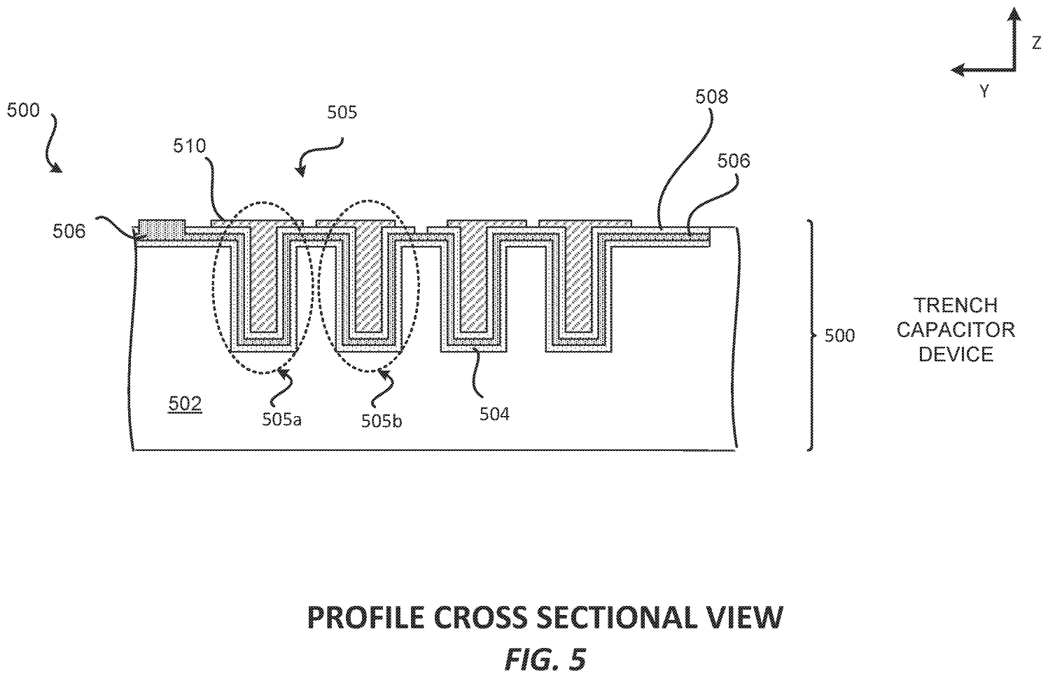

FIG. 5 illustrates a cross sectional profile view of a passive device 500 that is configured as a trench capacitor device. The passive device 500 may be an integrated passive device that includes multiple trench capacitors (e.g., deep trench capacitors). The passive device 500 may be a means for trench capacitance. The passive device 500 may represent the passive device 180 and/or the passive device 182, that are located at least partially in the passive component block 108. The passive device 500 includes a front side and a back side. The front side of the passive device 500 may include the plurality of trench capacitors.

The passive device 500 includes a passive device substrate 502 and a plurality of trench capacitors 505. A plurality of solder interconnects (not shown) may be coupled to the passive device 500. The passive device substrate 502 may include silicon (Si). The passive device substrate 502 may include a plurality of trenches and/or cavities over which capacitors may be formed.

The plurality of trench capacitors 505 include a trench capacitor 505a and a trench capacitor 505b. The trench capacitor 505a and the trench capacitor 505b may be configured to be part of a same capacitor (e.g., first capacitor, first trench capacitor). The trench capacitor 505a and the trench capacitor 505b may be configured to be coupled to and/or part of a first power distribution network (PDN). The trench capacitor 505a and the trench capacitor 505b may be configured to be part of a first electrical path for a first power for a package. The trench capacitor 505a and the trench capacitor 505b may be configured to be coupled to integrated device(s).

As shown in FIG. 5, the passive device 500 includes the passive device substrate 502, an oxide layer 504, a first electrically conductive layer 506, a dielectric layer 508, and a second electrically conductive layer 510. The first electrically conductive layer 506 and/or the second electrically conductive layer 510 may include polysilicon. The oxide layer 504 and/or the dielectric layer 508 may include SiO₂ (e.g., low-pressure chemical vapor deposition (LPCVD) SiO₂) or Si₃N₄ (e.g., LPCVD Si₃N₄). Portions of the oxide layer 504, the first electrically conductive layer 506, the dielectric layer 508, and the second electrically conductive layer 510 may be located in trenches and/or cavities of the passive device substrate 502. It is noted that a passive device substrate 502 may be considered to have a trench or a cavity, even if the trench or the cavity is filled with one or more materials.

The trench capacitor 505a (e.g., first trench capacitor, first capacitor, means for first trench capacitance) may be defined by (i) a first portion of the oxide layer 504, (ii) a first portion of the first electrically conductive layer 506, (iii) a first portion of the dielectric layer 508, and (iv) a first portion of the second electrically conductive layer 510 that are located in a trench (e.g., first trench) of the passive device substrate 502.

The trench capacitor 505b (e.g., second trench capacitor, second capacitor, means for second trench capacitance) may be defined by (i) a second portion of the oxide layer 504, (ii) a second portion of the first electrically conductive layer 506, (iii) a second portion of the dielectric layer 508, and (iv) a second portion of the second electrically conductive layer 510 that are located in a trench (e.g., second trench) of the passive device substrate 502. It is noted that trench capacitor 505b may be part of a same capacitor as the trench capacitor 505a. That is, the trench capacitor 505a and the trench capacitor 505b may be configured to be electrically coupled together to form a capacitor (e.g., first capacitor) with a greater capacitance.

The front side of the passive device 500 may be a side that includes the trench capacitors. Portions of the second electrically conductive layer 510 may be configured as pad interconnects of the passive device 500. Similarly, portions of the first electrically conductive layer 506 may be configured as pad interconnects of the passive device 500. The front side of the passive device 500 may be a side that includes the first electrically conductive layer 506 and/or the second electrically conductive layer 510, that are configured as pad interconnects.

An integrated device may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include transistors. An integrated device may be an example of an electrical component and/or electrical device. In some implementations, an integrated device may include a chiplet. A chiplet may be fabricated using a process that provides better yields compared to other processes that are used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

### Exemplary Sequence for Fabricating a Passive Component Block

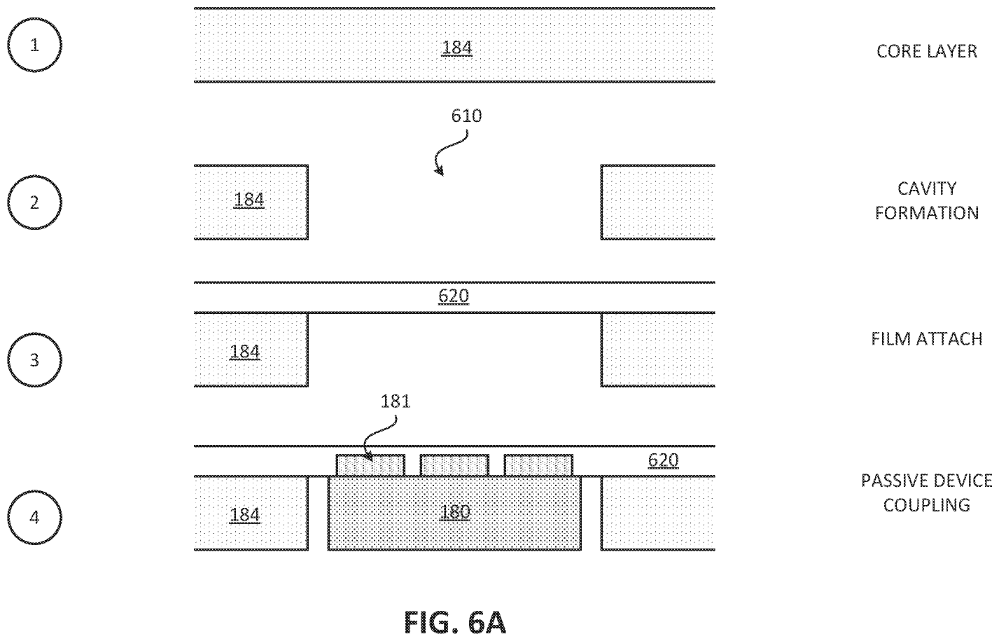

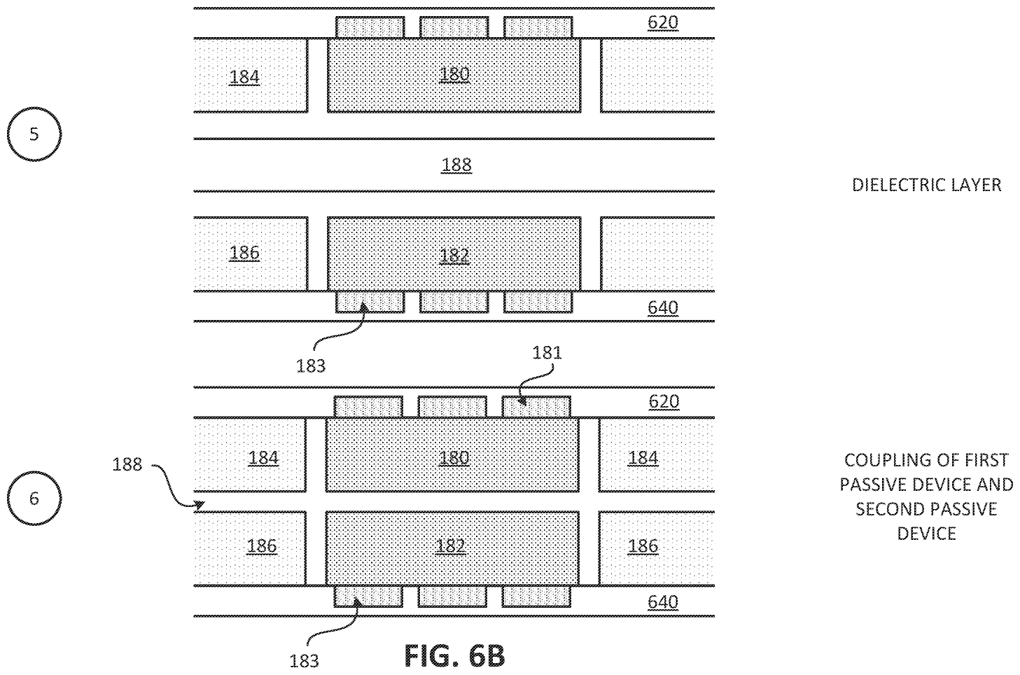

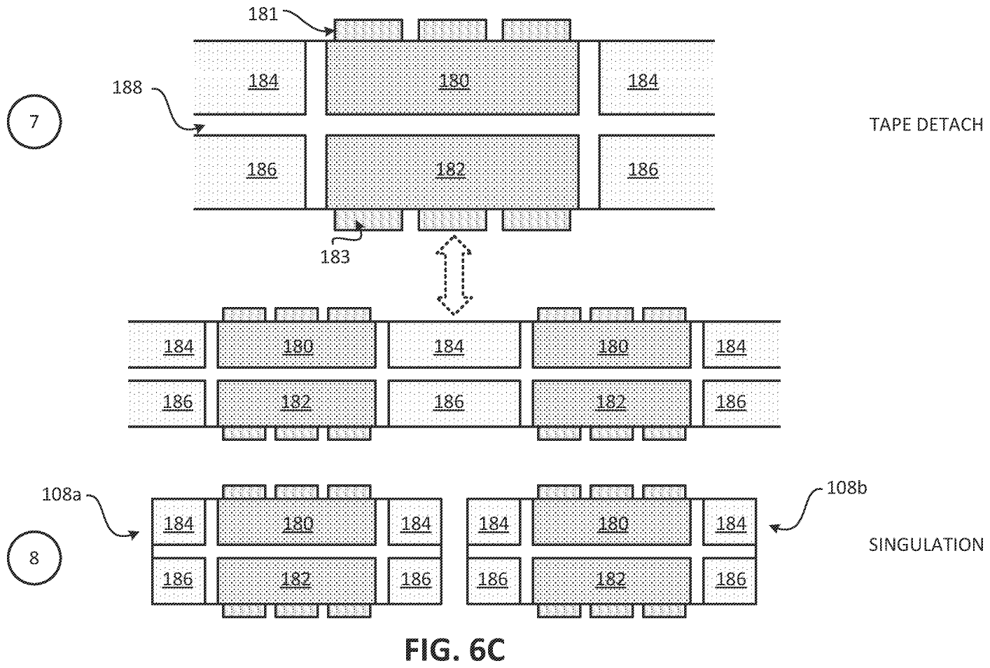

FIGS. 6A-6C illustrate an exemplary sequence for providing or fabricating a passive component block. In some implementations, the sequence of FIGS. 6A-6C may be used to provide or fabricate any of the passive component block described in the disclosure. In some implementations, the sequence of FIGS. 6A-6C may be used to provide or fabricate the passive component block 108 described in the disclosure.

It should be noted that the sequence of FIGS. 6A-6C may combine one or more stages in order to simplify and/or clarify the sequence for providing or fabricating a passive component block. In some implementations, the order of the processes may be changed or modified. In some implementations, one or more of processes may be replaced or substituted without departing from the spirit of the disclosure. Different implementations may fabricate a passive component block differently.

Stage 1, as shown in FIG. 6A, illustrates a state after a block core layer 184 is provided. The block core layer 184 may include one or more seed layer(s) coupled to surface(s) of the block core layer 184. The block core layer 184 may be a core layer. The core layer may include a dielectric layer.

Stage 2 illustrates a state after a cavity 610 is formed in the block core layer 184. A laser process (e.g., laser ablation) may be used to form the cavity 610. However, different implementations may use different processes to form the cavity 610. The cavity 610 may extend through the thickness of the block core layer 184 (and seed layers if seed layers are present).

Stage 3 illustrates a state after the block core layer 184 with the cavity 610 is coupled to a tape 620. The tape 620 may be a type of carrier and/or a film. The tape 620 may include an adhesive.

Stage 4 illustrates a state after a passive device 180 that includes a plurality of pad interconnects 181, is coupled to the tape 830. The passive device 180 is coupled to the tape 620 through the cavity 610 in the block core layer 184. The passive device 180 is located at least partially in the cavity 610 of the block core layer 184. The plurality of pad interconnects 181 may be touching the tape 620. The tape 620, the block core layer 184 and the passive device 180 may be part of a panel (e.g., first panel).

Stage 5, as shown in FIG. 6B, illustrates a block core layer 184, the passive device 180 and the tape 620. Stage 5 also illustrates a block core layer 186, a passive device 182, a tape 640. The tape 640, the block core layer 186 and the passive device 182 may be part of a panel (e.g., second panel). The block core layer 186, the passive device 182 and the tape 640 may be coupled together in a similar manner as the block core layer 184, the passive device 180 and the tape 620. Stages 1 through 4 of FIG. 6A, may be used to fabricate the block core layer 186, the passive device 182 and the tape 640.

Stage 5 also illustrate a dielectric layer 188. Different implementations may use different types of dielectric for the dielectric layer 188.

Stage 6 illustrates the block core layer 184, the passive device 180 and the tape 620 coupled to the block core layer 186, the passive device 182 and the tape 640 through the dielectric layer 188. A lamination process may be used to couple the block core layer 184, the passive device 180 and the tape 620 to the block core layer 186, the passive device 182 and the tape 640 through the dielectric layer 188. A first panel comprising the tape 620, the block core layer 184 and the passive device 180 may be coupled to a second panel comprising the tape 640, the block core layer 186 and the passive device 182. The back side of the passive device 180 may face the back side of the passive device 182. The dielectric layer 188 may be located between the passive device 180 and the passive device 182. The dielectric layer 188 may be located between the passive device 180 and the block core layer 184. The dielectric layer 188 may be located between the passive device 182 and the block core layer 186.

Stage 7, as shown in FIG. 6C illustrates a state after the tape 620 and the tape 640 are decoupled. The tape 620 may be detached from the block core layer 184, the passive device 180 and the dielectric layer 188. The tape 640 may be detached from the block core layer 186, the passive device 182 and the dielectric layer 188. Stage 7 may also illustrate a panel that includes the block core layer 184, the block core layer 186, a plurality of passive devices 180, a plurality of passive devices 182 and the dielectric layer 188.

Stage 8 illustrates a state after the panel(s) has/have been singulated into a plurality of passive component blocks, with each passive component block including a passive device 180, a passive device 182, a block core layer 184, a block core layer 186 and a dielectric layer 188. Stage 8 illustrates and example of a passive component block 108a and a passive component block 108b.

### Exemplary Flow Diagram of a Method for Fabricating a Passive Component Block

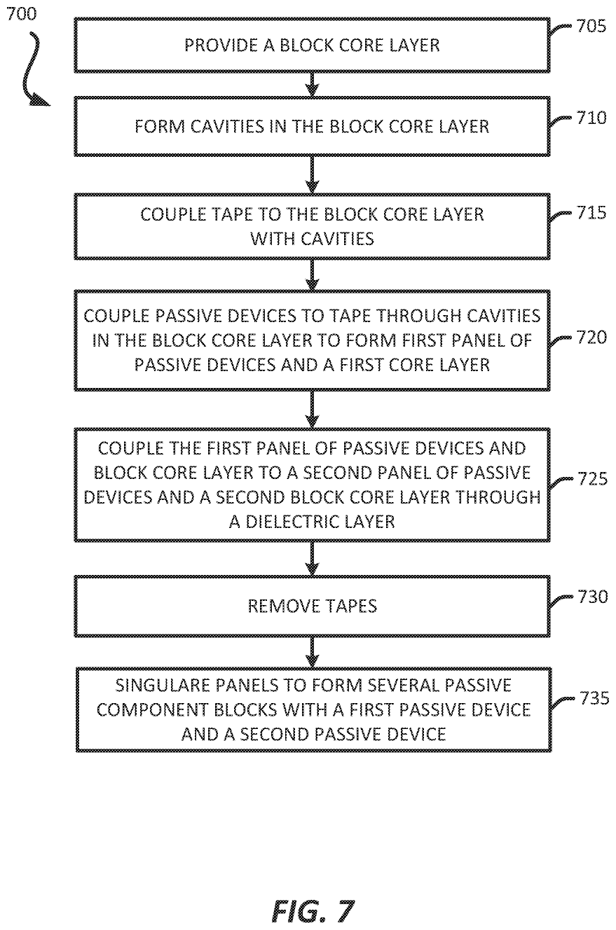

In some implementations, fabricating a passive component block includes several processes. FIG. 7 illustrates an exemplary flow diagram of a method 700 for providing or fabricating a passive component block. In some implementations, the method 700 of FIG. 7 may be used to provide or fabricate the passive component block 108.

It should be noted that the method 700 of FIG. 7 may combine one or more processes in order to simplify and/or clarify the method for providing or fabricating a passive component block. In some implementations, the order of the processes may be changed or modified.

The method provides (at 705) a block core layer. Stage 1 of FIG. 6A, illustrates and describes an example of a state after a block core layer 184 is provided. The block core layer 184 may include one or more seed layer(s) coupled to surface(s) of the block core layer 184. The block core layer 184 may be a core layer. The core layer may include a dielectric layer.

The method forms (at 710) a plurality of cavities in the block core layer. Stage 2 of FIG. 6A, illustrates and describes an example of a state after a cavity 610 is formed in the block core layer 184. A laser process (e.g., laser ablation) may be used to form the cavity 610. However, different implementations may use different processes to form the cavity 610. The cavity 610 may extend through the thickness of the block core layer 184 (and seed layers if seed layers are present).

The method couples (at 715) the block core layer with the cavities to a tape. Stage 3 of FIG. 6A, illustrates and describes an example of a state after the block core layer 184 with the cavity 610 is coupled to a tape 620. The tape 620 may be a type of carrier and/or a film. The tape 620 may include an adhesive.

The method couples (at 720) a plurality of passive devices to the tape through cavities in the block core layer. Stage 4 of FIG. 6A, illustrates and describes an example of a state after a passive device 180 that includes a plurality of pad interconnects 181, is coupled to the tape 830. The passive device 180 is coupled to the tape 620 through the cavity 610 in the block core layer 184. The passive device 180 is located at least partially in the cavity 610 of the block core layer 184. The plurality of pad interconnects 181 may be touching the tape 620. The tape 620, the block core layer 184 and the passive device 180 may be part of a panel (e.g., first panel).

The method couples (at 725) a first panel comprising a first plurality of passive devices and a first block core layer to a second panel comprising a second plurality of passive devices and a second block core layer. Stage 5 of FIG. 6B, illustrates and describes an example of a block core layer 184, the passive device 180 and the tape 620. Stage 5 also illustrates a block core layer 186, a passive device 182, a tape 640. The tape 640, the block core layer 186 and the passive device 182 may be part of a panel (e.g., second panel). The block core layer 186, the passive device 182 and the tape 640 may be coupled together in a similar manner as the block core layer 184, the passive device 180 and the tape 620. Stages 1 through 4 of FIG. 6A, may be used to fabricate the block core layer 186, the passive device 182 and the tape 640. Stage 5 also illustrate a dielectric layer 188. Different implementations may use different types of dielectric for the dielectric layer 188.

Stage 6 of FIG. 6B, illustrates and describes an example of a state after the block core layer 184, the passive device 180 and the tape 620 are coupled to the block core layer 186, the passive device 182 and the tape 640 through the dielectric layer 188. A lamination process may be used to couple the block core layer 184, the passive device 180 and the tape 620 to the block core layer 186, the passive device 182 and the tape 640 through the dielectric layer 188. A first panel comprising the tape 620, the block core layer 184 and the passive device 180 may be coupled to a second panel comprising the tape 640, the block core layer 186 and the passive device 182. The back side of the passive device 180 may face the back side of the passive device 182. The dielectric layer 188 may be located between the passive device 180 and the passive device 182. The dielectric layer 188 may be located between the passive device 180 and the block core layer 184. The dielectric layer 188 may be located between the passive device 182 and the block core layer 186.

The method removes (at 730) tapes. Stage 7 of FIG. 6C illustrates and describes an example of a state after the tape 620 and the tape 640 are decoupled. The tape 620 may be detached from the block core layer 184, the passive device 180 and the dielectric layer 188. The tape 640 may be detached from the block core layer 186, the passive device 182 and the dielectric layer 188. Stage 7 may also illustrate a panel that includes the block core layer 184, the block core layer 186, a plurality of passive devices 180, a plurality of passive devices 182 and the dielectric layer 188.

The method singulates (at 735) the panels to form individual passive component blocks. Stage 8 of FIG. 6C, illustrates and describes an example of a state after the panel(s) has/have been singulated into a plurality of passive component blocks, with each passive component block including a passive device 180, a passive device 182, a block core layer 184, a block core layer 186 and a dielectric layer 188. Stage 8 illustrates a passive component block 108a and a passive component block 108b.

### Exemplary Sequence for Fabricating a Substrate With a Passive Component Block

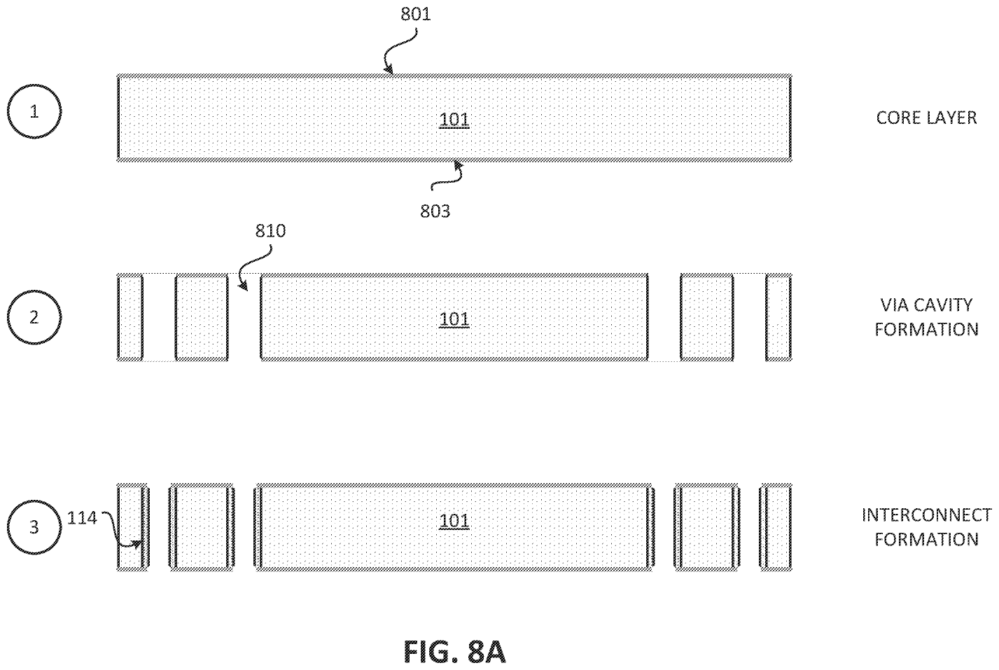

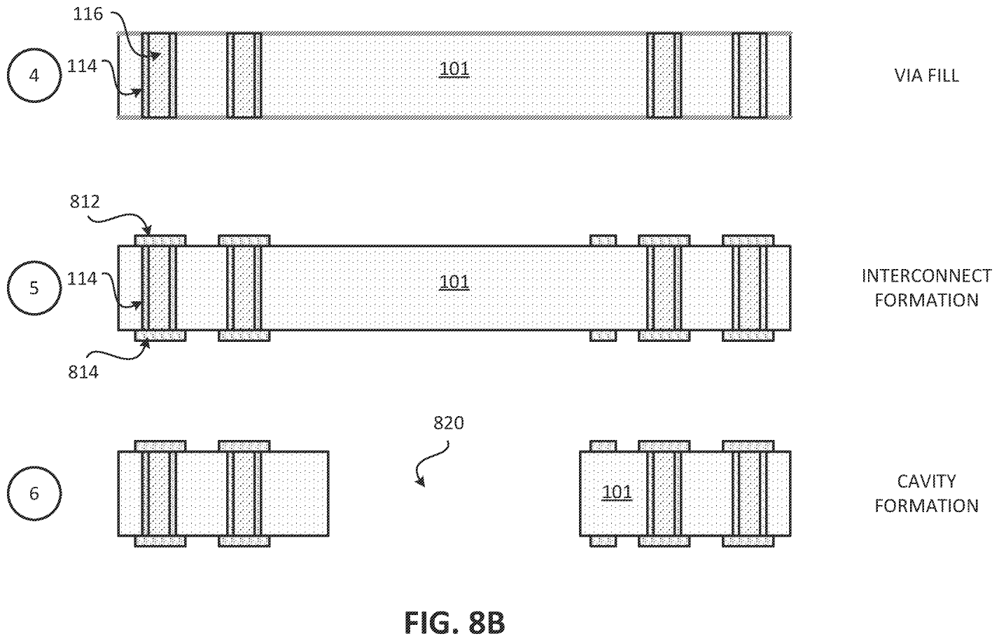

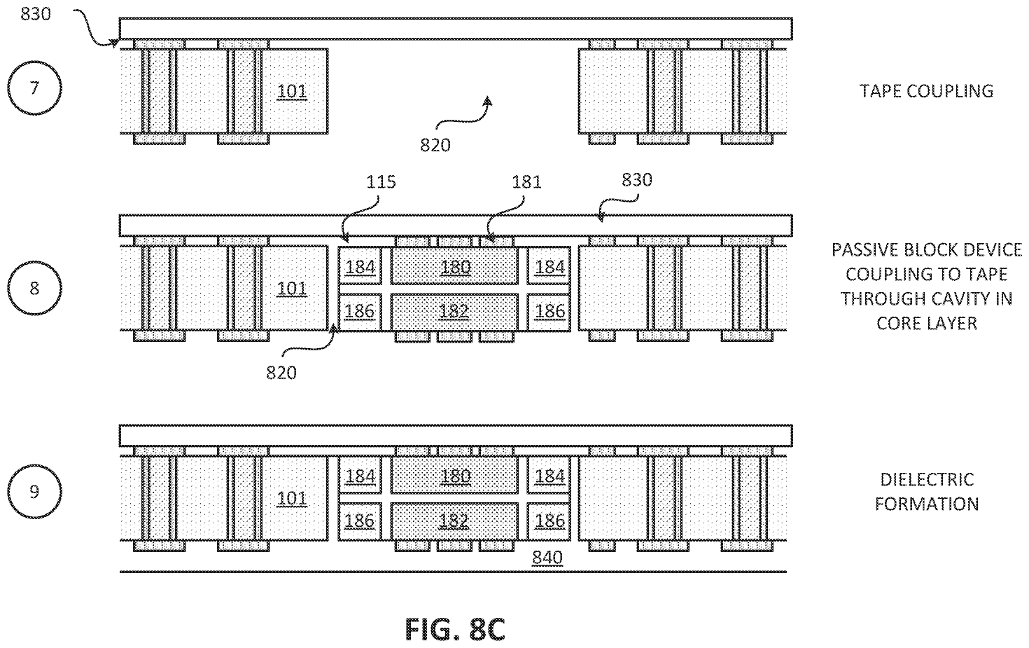

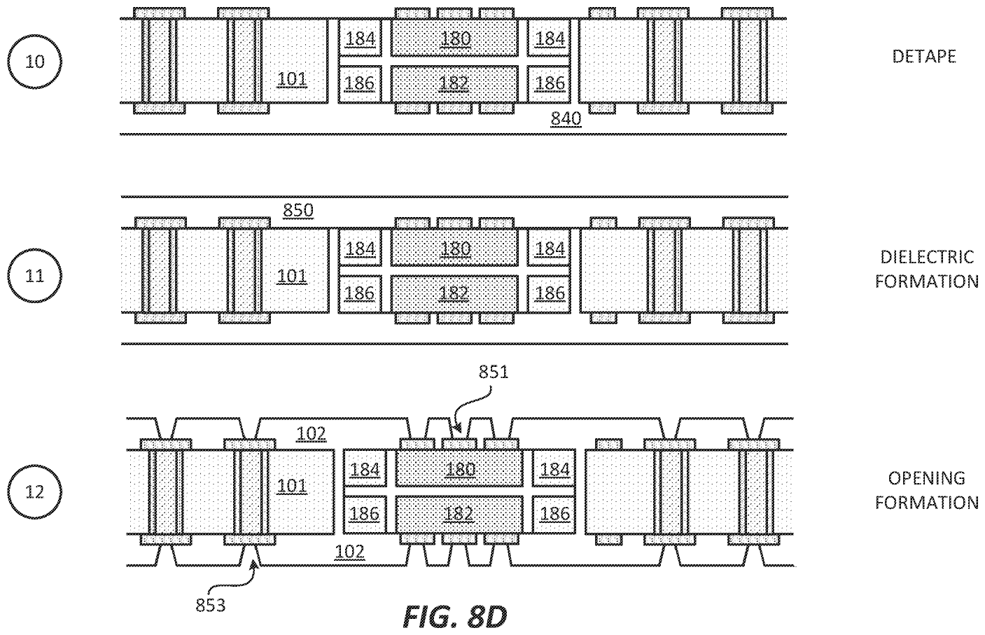

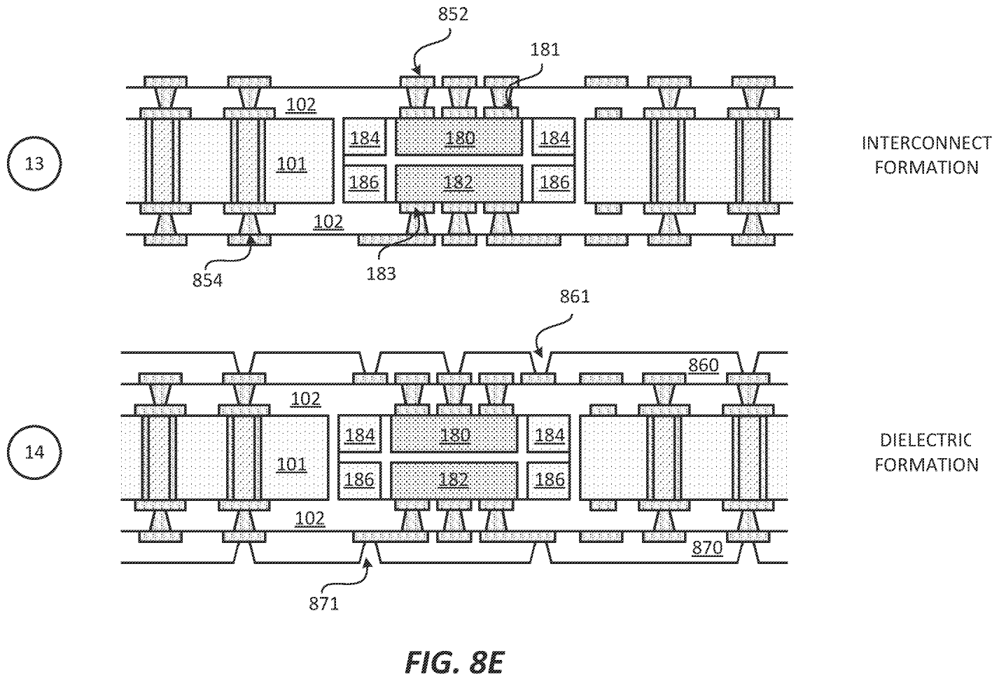

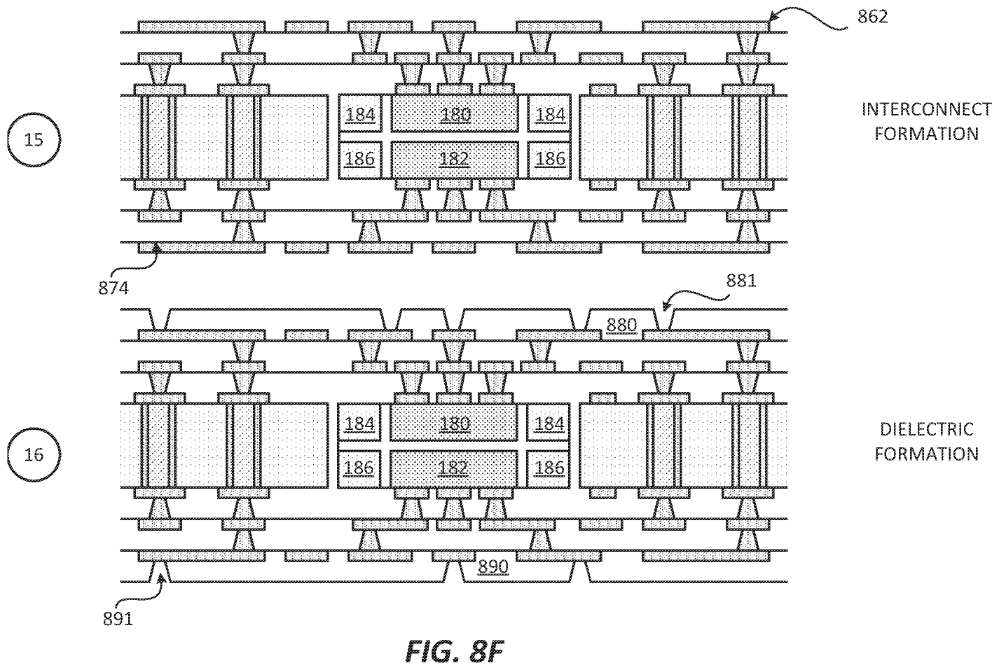

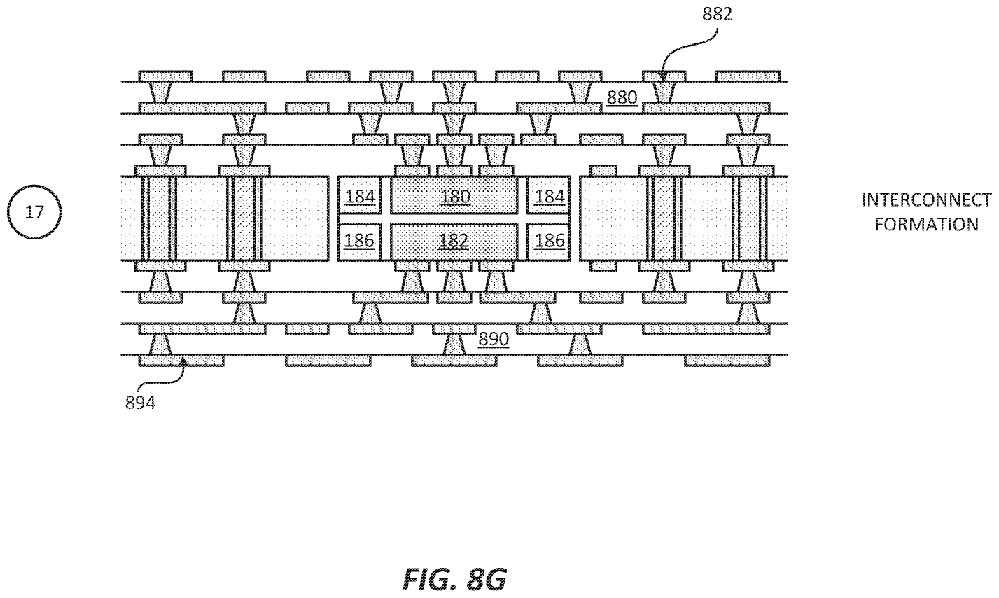

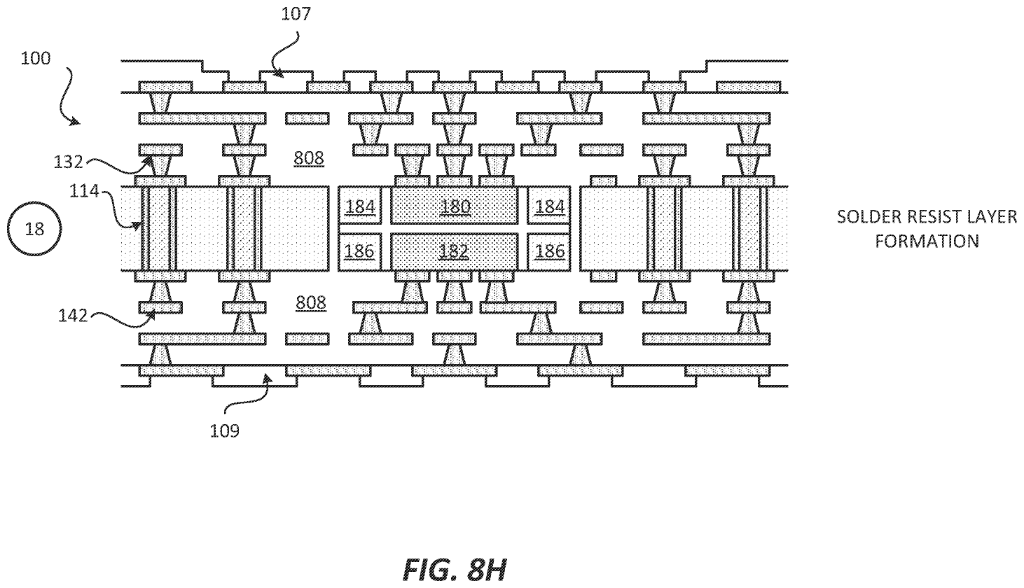

FIGS. 8A-8H illustrate an exemplary sequence for providing or fabricating a substrate with a passive component block. In some implementations, the sequence of FIGS. 8A-8H may be used to provide or fabricate any of the substrates described in the disclosure. In some implementations, the sequence of FIGS. 8A-8H may be used to provide or fabricate the substrate 100 described in the disclosure.

It should be noted that the sequence of FIGS. 8A-8H may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 8A, illustrates a state after a core layer 101 is provided. The core layer 101 may include a seed layer 801 coupled to a first surface of the core layer 101 and a seed layer 803 coupled to a second surface of the core layer 101.

Stage 2 illustrates a state after a plurality of cavities 810 (e.g., via cavities) are formed in the core layer 101. The plurality of cavities 810 may be formed through the seed layer 801 and the seed layer 803. A laser process (e.g., laser ablation) may be used to form the plurality of cavities 810. However, different implementations may use different processes to form the plurality of cavities 810. The plurality of cavities 810 may extend through the thickness of the core layer 101, the seed layer 801 and/or the seed layer 803.

Stage 3 illustrates a state after a plurality of via interconnects 114 are formed. The plurality of via interconnects 114 may be formed in the plurality of cavities 810. A plating process and a patterning process may be used to form the plurality of via interconnects 114. Part of the plurality of cavities may still be present after the plurality of via interconnects 114 are formed. In some implementations, a majority or all portions of the plurality of cavities 810 are filled with the plurality of via interconnects 114 (or plurality of via interconnects 314).

Stage 4, as shown in FIG. 8B, illustrates a state after a plurality of fills 116 is provided in the plurality of cavities 810. The plurality of fills 116 may be located between the walls of the plurality of via interconnects. 114. The plurality of fills 116 may include a type of dielectric layer. The plurality of fills 116 may occupy a space in the plurality of cavities 810 that is not occupied by the plurality of via interconnects 114.

Stage 5 illustrates a state after a plurality of interconnects 812 and a plurality of interconnects 814 are formed. The plurality of interconnects 812 may be formed and coupled to a first surface of the core layer 101. In some implementations, part of the seed layer 801 may be part of the plurality of interconnects 812. The plurality of interconnects 812 may be coupled to the plurality of via interconnects 114. The plurality of interconnects 814 may be formed and coupled to a second surface of the core layer 101. In some implementations, part of the seed layer 803 may be part of the plurality of interconnects 814. The plurality of interconnects 814 may be coupled to the plurality of via interconnects 114. A plating process and a patterning process may be used to form the plurality of interconnects 812 and/or the plurality of interconnects 814.

Stage 6 illustrates a state after a cavity 820 is formed in the core layer 101. The cavity 820 may be formed through the core layer 101. A laser process (e.g., laser ablation) may be used to form the cavity 820. However, different implementations may use different processes to form the cavity 820. The cavity 820 may extend through the thickness of the core layer 101.

Stage 7, as shown in FIG. 8C, illustrates a state after the core layer 101 with the cavity 820 is coupled to a tape 830. The tape 830 may be a type of carrier. The tape 830 may include an adhesive. The tape 830 may be touching the plurality of interconnects 812 and/or the core layer 101.

Stage 8 illustrates a state after a passive component block 108 is coupled to the tape 830. The passive component block 108 is coupled to the tape 830 through the cavity 820 in the core layer 101. The passive component block 108 is located at least partially in the cavity 820 of the core layer 101. The plurality of pad interconnects 181 may be coupled and touching the tape 830.

Stage 9 illustrates a state after a dielectric layer 840 is formed. The dielectric layer 840 fills at least part of the cavity 820 of the core layer 101. The dielectric layer 840 is coupled to the passive component block 108 and the core layer 101. The dielectric layer 840 may be coupled to a second surface (e.g., bottom surface) of the core layer 101. A deposition process and/or a lamination process may be used to form the dielectric layer 840. In some implementations, the dielectric layer 840 may include a polymer. In some implementations, the dielectric layer 840 may include prepreg. In some implementations, the dielectric layer 840 may include die attach film.

Stage 10, as shown in FIG. 8D, illustrates a state after the tape 830 is decoupled from the core layer 101 and the passive component block 108. The tape 830 may be detached and/or peeled off.

Stage 11 illustrates a state after the dielectric layer 850 is formed and coupled to the core layer 101 and the passive component block 108. The dielectric layer 850 may fill part of the cavity 820. The dielectric layer 850 may be coupled to the passive component block 108 and a first surface (e.g., top surface) of the core layer. A deposition process and/or a lamination process may be used to form the dielectric layer 850. In some implementations, the dielectric layer 850 may include a polymer. In some implementations, the dielectric layer 850 may include prepreg. In some implementations, the dielectric layer 850 may include die attach film. The dielectric layer 850 may be the same material as the dielectric layer 840. The dielectric layer 840 and the dielectric layer 850 may be represented as the dielectric layer 102. The dielectric layer 102 is coupled to the core layer 101 and the passive component block 108.

Stage 12 illustrates a state after a plurality of cavities 851 are formed through a surface (e.g., first surface, top surface) of the dielectric layer 102. The plurality of cavities 851 may expose part of the plurality of pad interconnects 112 of the passive component block 108. A laser process (e.g., laser ablation process) may be used to form the plurality of cavities 851 in the dielectric layer 102. However, different implementations may use different processes to form the plurality of cavities 851. The plurality of cavities 851 may have different shapes.

Stage 12 also illustrates a state after a plurality of cavities 853 are formed through another surface (e.g., second surface, bottom surface) of the dielectric layer 102. A laser process (e.g., laser ablation process) may be used to form the plurality of cavities 853 in the dielectric layer 102. However, different implementations may use different processes to form the plurality of cavities 853.

Stage 13, as shown in FIG. 8E, illustrates a state after a plurality of interconnects 852 and a plurality of interconnects 854 are formed in at least the dielectric layer 102. Some interconnects (e.g., via interconnects) from the plurality of interconnects 852 may be directly touching the plurality of pad interconnects 181 of the passive component block 108. Some interconnects (e.g., via interconnects) from the plurality of interconnects 854 may be directly touching the plurality of pad interconnects 183 of the passive component block 108. A plating process may be used to form the plurality of interconnects 852 and a plurality of interconnects 854.

Stage 14 illustrates a state after a dielectric layer 860 and the dielectric layer 870 are formed. The dielectric layer 860 may include a plurality of cavities 861. The dielectric layer 870 may include a plurality of cavities 871. The dielectric layer 860 may be formed and coupled to a first surface (e.g., top surface) of the dielectric layer 102. The dielectric layer 870 may be formed and coupled to a second surface (e.g., bottom surface) of the dielectric layer 102. In some implementations, the dielectric layer 860 and/or the dielectric layer 870 may include a polymer. In some implementations, the dielectric layer 860 and/or the dielectric layer 870 may include Ajinomoto Build-up Film (ABF). In some implementations, the dielectric layer 860 and/or the dielectric layer 870 may include prepreg. The dielectric layer 860 and/or the dielectric layer 870 may be the same or different from the dielectric layer 102.

The plurality of cavities 861 are formed through a surface (e.g., first surface, top surface) of the dielectric layer 860. A laser process (e.g., laser ablation process) may be used to form the plurality of cavities 861 in the dielectric layer 860. However, different implementations may use different processes to form the plurality of cavities 861. The plurality of cavities 871 are formed through a surface (e.g., second surface, bottom surface) of the dielectric layer 870. A laser process (e.g., laser ablation process) may be used to form the plurality of cavities 871 in the dielectric layer 870. However, different implementations may use different processes to form the plurality of cavities 871. In some implementations, the dielectric layer 860, the dielectric layer 870, the plurality of cavities 861 and/or the plurality of cavities 871 may be formed through a deposition process, a lamination process, an exposure process and/or a development process.

Stage 15, as shown in FIG. 8F, illustrates a state after a plurality of interconnects 862 are formed in at least the dielectric layer 860. The plurality of interconnects 862 are coupled to the plurality of interconnects 852. Stage 15 also illustrates and describes a state after a plurality of interconnects 874 are formed in at least the dielectric layer 870. The plurality of interconnects 874 are coupled to the plurality of interconnects 854. A plating process and a patterning process may be used to form the plurality of interconnects 862 and/or the plurality of interconnects 874.

Stage 16 illustrates a state after a dielectric layer 880 and the dielectric layer 890 are formed. The dielectric layer 880 may include a plurality of cavities 881. The dielectric layer 890 may include a plurality of cavities 891. The dielectric layer 880 may be formed and coupled to a first surface (e.g., top surface) of the dielectric layer 860. The dielectric layer 890 may be formed and coupled to a second surface (e.g., bottom surface) of the dielectric layer 870. In some implementations, the dielectric layer 880 and/or the dielectric layer 890 may include a polymer. In some implementations, the dielectric layer 880 and/or the dielectric layer 890 may include Ajinomoto Build-up Film (ABF). In some implementations, the dielectric layer 880 and/or the dielectric layer 890 may include prepreg. The dielectric layer 880 and/or the dielectric layer 890 may be the same or different from the dielectric layer 102, the dielectric layer 860 and/or the dielectric layer 870.

The plurality of cavities 881 are formed through a surface (e.g., first surface, top surface) of the dielectric layer 880. A laser process (e.g., laser ablation process) may be used to form the plurality of cavities 881 in the dielectric layer 880. However, different implementations may use different processes to form the plurality of cavities 881. The plurality of cavities 891 are formed through a surface (e.g., second surface, bottom surface) of the dielectric layer 890. A laser process (e.g., laser ablation process) may be used to form the plurality of cavities 891 in the dielectric layer 890. However, different implementations may use different processes to form the plurality of cavities 891. In some implementations, the dielectric layer 880, the dielectric layer 890, the plurality of cavities 881 and/or the plurality of cavities 891 may be formed through a deposition process, a lamination process, an exposure process and/or a development process.

Stage 17, as shown in FIG. 8G, illustrates a state after a plurality of interconnects 882 are formed in at least the dielectric layer 880. The plurality of interconnects 882 are coupled to the plurality of interconnects 862. Stage 17 also illustrates and describes a state after a plurality of interconnects 894 are formed in at least the dielectric layer 890. The plurality of interconnects 894 are coupled to the plurality of interconnects 874. A plating process and a patterning process may be used to form the plurality of interconnects 882 and/or the plurality of interconnects 894.

Stage 18, as shown in FIG. 8H, illustrates a state after a solder resist layer 107 is formed and patterned. The solder resist layer 107 may be coupled to the dielectric layer 808. The dielectric layer 808 may be at least one dielectric layer that represents all and/or part of, the dielectric layer 102, the dielectric layer 860, the dielectric layer 870, the dielectric layer 880 and/or a dielectric layer 890. A deposition, a lamination, an exposure, a development and/or an etching process may be used to form and pattern the solder resist layer 107. The plurality of interconnects 132 may be located at least in the dielectric layer 808. The plurality of interconnects 132 may represent all and/or part of the plurality of interconnects 812, the plurality of interconnects 852, the plurality of interconnects 862 and/or the plurality of interconnects 882.

Stage 18 also illustrates and describes a state after a solder resist layer 109 is formed and patterned. The solder resist layer 109 may be coupled to the dielectric layer 808. A deposition, a lamination, an exposure, a development and/or an etching process may be used to form and pattern the solder resist layer 109. The plurality of interconnects 142 may be located at least in the dielectric layer 809. The plurality of interconnects 142 may represent all and/or part of the plurality of interconnects 814, the plurality of interconnects 854, the plurality of interconnects 874 and/or the plurality of interconnects 894.

### Exemplary Flow Diagram of a Method for Fabricating a Substrate With a Passive Component Block

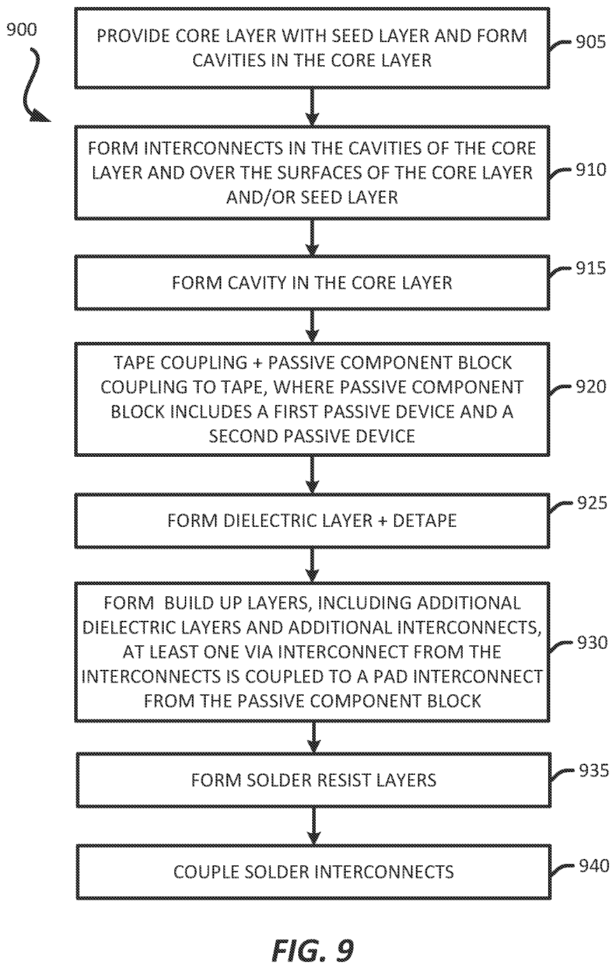

In some implementations, fabricating a substrate includes several processes. FIG. 9 illustrates an exemplary flow diagram of a method 900 for providing or fabricating a substrate with a passive component block. In some implementations, the method 900 of FIG. 9 may be used to provide or fabricate the substrate 100.

It should be noted that the method 900 of FIG. 9 may combine one or more processes in order to simplify and/or clarify the method for providing or fabricating a substrate. In some implementations, the order of the processes may be changed or modified.

The method provides (at 905) a core layer with seed layers and forms cavities (e.g., via cavities) in the core layer through the seed layer. Stage 1 of FIG. 8A, illustrates and describes an example of a state after a core layer 101 is provided. The core layer 101 may include a seed layer 801 coupled to a first surface of the core layer 101 and a seed layer 803 coupled to a second surface of the core layer 101.

Stage 2 of FIG. 8A, illustrates and describes an example of a state after a plurality of cavities 810 (e.g., via cavities) are formed in the core layer 101. The plurality of cavities 810 may be formed through the seed layer 801 and the seed layer 803. A laser process (e.g., laser ablation) may be used to form the plurality of cavities 810. However, different implementations may use different processes to form the plurality of cavities 810. The plurality of cavities 810 may extend through the thickness of the core layer 101. the seed layer 801 and/or the seed layer 803.

The method forms (at 910) via interconnects in the cavities of the core layer and on surfaces of the core layer. The via interconnects may also include a plurality of fills. Stage 3 of FIG. 8A, illustrates and describes an example of a state after a plurality of via interconnects 114 are formed. The plurality of via interconnects 114 may be formed in the plurality of cavities 810. A plating process and a patterning process may be used to form the plurality of via interconnects 114. Part of the plurality of cavities may still be present after the plurality of via interconnects 114 are formed. In some implementations, a majority or all portions of the plurality of cavities 810 are filled with the plurality of via interconnects 114 (or plurality of via interconnects 314).

Stage 4 of FIG. 8B, illustrates and describes an example of a state after a plurality of fills 116 is provided in the plurality of cavities 810. The plurality of fills 116 may be located between the walls of the plurality of via interconnects. 114. The plurality of fills 116 may include a type of dielectric layer. The plurality of fills 116 may occupy a space in the plurality of cavities 810 that is not occupied by the plurality of via interconnects 114.

Stage 5 of FIG. 8B, illustrates and describes an example of a state after a plurality of interconnects 812 and a plurality of interconnects 814 are formed. The plurality of interconnects 812 may be formed and coupled to a first surface of the core layer 101. In some implementations, part of the seed layer 801 may be part of the plurality of interconnects 812. The plurality of interconnects 812 may be coupled to the plurality of via interconnects 114. The plurality of interconnects 814 may be formed and coupled to a second surface of the core layer 101. In some implementations, part of the seed layer 803 may be part of the plurality of interconnects 814. The plurality of interconnects 814 may be coupled to the plurality of via interconnects 114. A plating process and a patterning process may be used to form the plurality of interconnects 812 and/or the plurality of interconnects 814.

The method forms (at 915) a cavity in the core layer. Stage 6 of FIG. 8B, illustrates and describes an example of a state after a cavity 820 is formed in the core layer 101. The cavity 820 may be formed through the core layer 101. A laser process (e.g., laser ablation) may be used to form the cavity 820. However, different implementations may use different processes to form the cavity 820. The cavity 820 may extend through the thickness of the core layer 101.

The method couples (at 920) a core layer to a tape. Stage 7 of FIG. 8C. illustrates and describes an example of a state after the core layer 101 with the cavity 820 is coupled to a tape 830. The tape 830 may be a type of carrier. The tape 830 may include an adhesive. The tape 830 may be touching the plurality of interconnects 812 and/or the core layer 101.

The method also couples (at 920) a passive component block to the tape. The passive component block includes a first passive device and a second passive device. Stage 8 of FIG. 8C, illustrates and describes an example of a state after a passive component block 108 is coupled to the tape 830. The passive component block 108 is coupled to the tape 830 through the cavity 820 in the core layer 101. The passive component block 108 is located at least partially in the cavity 820 of the core layer 101. The plurality of pad interconnects 181 may be coupled and touching the tape 830.

The method forms (at 925) a dielectric layer. Stage 9 of FIG. 8C, illustrates and describes an example of a state after a dielectric layer 840 is formed. The dielectric layer 840 fills at least part of the cavity 820 of the core layer 101. The dielectric layer 840 is coupled to the passive component block 108 and the core layer 101. The dielectric layer 840 may be coupled to a second surface (e.g., bottom surface) of the core layer 101. A deposition process and/or a lamination process may be used to form the dielectric layer 840. In some implementations, the dielectric layer 840 may include a polymer. In some implementations, the dielectric layer 840 may include prepreg. In some implementations, the dielectric layer 840 may include die attach film.

The method decouples (at 925) the tape. Stage 10 of FIG. 8D, illustrates and describes an example of a state after the tape 830 is decoupled from the core layer 101 and the passive component block 108. The tape 830 may be detached and/or peeled off.

The method forms (at 930) buildup layers, including additional dielectric layers and interconnects. Stage 11 of FIG. 8D through Stage 17 of FIG. 8G, illustrate and describe examples of forming build up layers that includes at least one dielectric layer and a plurality of interconnects.

Stage 11 of FIG. 8D, illustrates and describes an example of a state after the dielectric layer 850 is formed and coupled to the core layer 101 and the passive component block 108. The dielectric layer 850 may fill part of the cavity 820. The dielectric layer 850 may be coupled to the passive component block 108 and a first surface (e.g., top surface) of the core layer. A deposition process and/or a lamination process may be used to form the dielectric layer 850. In some implementations, the dielectric layer 850 may include a polymer. In some implementations, the dielectric layer 850 may include prepreg. In some implementations, the dielectric layer 850 may include die attach film. The dielectric layer 850 may be the same material as the dielectric layer 840. The dielectric layer 840 and the dielectric layer 850 may be represented as the dielectric layer 102. The dielectric layer 102 is coupled to the core layer 101 and the passive component block 108.

Stage 12 of FIG. 8D, illustrates and describes an example of a state after a plurality of cavities 851 are formed through a surface (e.g., first surface, top surface) of the dielectric layer 102. The plurality of cavities 851 may expose part of the plurality of pad interconnects 112 of the passive component block 108. A laser process (e.g., laser ablation process) may be used to form the plurality of cavities 851 in the dielectric layer 102. However, different implementations may use different processes to form the plurality of cavities 851. The plurality of cavities 851 may have different shapes.

Stage 12 also illustrates a state after a plurality of cavities 853 are formed through another surface (e.g., second surface, bottom surface) of the dielectric layer 102. A laser process (e.g., laser ablation process) may be used to form the plurality of cavities 853 in the dielectric layer 102. However, different implementations may use different processes to form the plurality of cavities 853.

Stage 13 of FIG. 8E, illustrates and describes an example of a state after a plurality of interconnects 852 and a plurality of interconnects 854 are formed in at least the dielectric layer 102. Some interconnects (e.g., via interconnects) from the plurality of interconnects 852 may be directly touching the plurality of pad interconnects 181 of the passive component block 108. Some interconnects (e.g., via interconnects) from the plurality of interconnects 854 may be directly touching the plurality of pad interconnects 183 of the passive component block 108. A plating process may be used to form the plurality of interconnects 852 and a plurality of interconnects 854.

Stage 14 of FIG. 8E, illustrates and describes an example of a state after a dielectric layer 860 and the dielectric layer 870 are formed. The dielectric layer 860 may include a plurality of cavities 861. The dielectric layer 870 may include a plurality of cavities 871. The dielectric layer 860 may be formed and coupled to a first surface (e.g., top surface) of the dielectric layer 102. The dielectric layer 870 may be formed and coupled to a second surface (e.g., bottom surface) of the dielectric layer 102. In some implementations, the dielectric layer 860 and/or the dielectric layer 870 may include a polymer. In some implementations, the dielectric layer 860 and/or the dielectric layer 870 may include Ajinomoto Build-up Film (ABF). In some implementations, the dielectric layer 860 and/or the dielectric layer 870 may include prepreg. The dielectric layer 860 and/or the dielectric layer 870 may be the same or different from the dielectric layer 102.

The plurality of cavities 861 are formed through a surface (e.g., first surface, top surface) of the dielectric layer 860. A laser process (e.g., laser ablation process) may be used to form the plurality of cavities 861 in the dielectric layer 860. However, different implementations may use different processes to form the plurality of cavities 861. The plurality of cavities 871 are formed through a surface (e.g., second surface, bottom surface) of the dielectric layer 870. A laser process (e.g., laser ablation process) may be used to form the plurality of cavities 871 in the dielectric layer 870. However, different implementations may use different processes to form the plurality of cavities 871. In some implementations, the dielectric layer 860, the dielectric layer 870, the plurality of cavities 861 and/or the plurality of cavities 871 may be formed through a deposition process, a lamination process, an exposure process and/or a development process.

Stage 15 of FIG. 8F, illustrates and describes an example of a state after a plurality of interconnects 862 are formed in at least the dielectric layer 860. The plurality of interconnects 862 are coupled to the plurality of interconnects 852. Stage 15 also illustrates and describes a state after a plurality of interconnects 874 are formed in at least the dielectric layer 870. The plurality of interconnects 874 are coupled to the plurality of interconnects 854. A plating process and a patterning process may be used to form the plurality of interconnects 862 and/or the plurality of interconnects 874.

Stage 16 of FIG. 8F, illustrates and describes an example of a state after a dielectric layer 880 and the dielectric layer 890 are formed. The dielectric layer 880 may include a plurality of cavities 881. The dielectric layer 890 may include a plurality of cavities 891. The dielectric layer 880 may be formed and coupled to a first surface (e.g., top surface) of the dielectric layer 860. The dielectric layer 890 may be formed and coupled to a second surface (e.g., bottom surface) of the dielectric layer 870. In some implementations, the dielectric layer 880 and/or the dielectric layer 890 may include a polymer. In some implementations, the dielectric layer 880 and/or the dielectric layer 890 may include Ajinomoto Build-up Film (ABF). In some implementations, the dielectric layer 880 and/or the dielectric layer 890 may include prepreg. The dielectric layer 880 and/or the dielectric layer 890 may be the same or different from the dielectric layer 102, the dielectric layer 860 and/or the dielectric layer 870.

The plurality of cavities 881 are formed through a surface (e.g., first surface, top surface) of the dielectric layer 880. A laser process (e.g., laser ablation process) may be used to form the plurality of cavities 881 in the dielectric layer 880. However, different implementations may use different processes to form the plurality of cavities 881. The plurality of cavities 891 are formed through a surface (e.g., second surface, bottom surface) of the dielectric layer 890. A laser process (e.g., laser ablation process) may be used to form the plurality of cavities 891 in the dielectric layer 890. However, different implementations may use different processes to form the plurality of cavities 891. In some implementations, the dielectric layer 880, the dielectric layer 890, the plurality of cavities 881 and/or the plurality of cavities 891 may be formed through a deposition process, a lamination process, an exposure process and/or a development process.

Stage 17 of FIG. 8G, illustrates and describes an example of a state after a plurality of interconnects 882 are formed in at least the dielectric layer 880. The plurality of interconnects 882 are coupled to the plurality of interconnects 862. Stage 17 also illustrates and describes a state after a plurality of interconnects 894 are formed in at least the dielectric layer 890. The plurality of interconnects 894 are coupled to the plurality of interconnects 874. A plating process and a patterning process may be used to form the plurality of interconnects 882 and/or the plurality of interconnects 894.

The method forms (at 935) at least one solder resist layer. Stage 18 of FIG. 8H, illustrates and describes an example of a state after a solder resist layer 107 is formed and patterned. The solder resist layer 107 may be coupled to the dielectric layer 808. The dielectric layer 808 may be at least one dielectric layer that represents all and/or part of, the dielectric layer 102, the dielectric layer 860, the dielectric layer 870, the dielectric layer 880 and/or a dielectric layer 890. A deposition, a lamination, an exposure, a development and/or an etching process may be used to form and pattern the solder resist layer 107. The plurality of interconnects 132 may be located at least in the dielectric layer 808. The plurality of interconnects 132 may represent all and/or part of the plurality of interconnects 812, the plurality of interconnects 852, the plurality of interconnects 862 and/or the plurality of interconnects 882.

Stage 18 also illustrates and describes a state after a solder resist layer 109 is formed and patterned. The solder resist layer 109 may be coupled to the dielectric layer 808. A deposition, a lamination, an exposure, a development and/or an etching process may be used to form and pattern the solder resist layer 109. The plurality of interconnects 142 may be located at least in the dielectric layer 809. The plurality of interconnects 142 may represent all and/or part of the plurality of interconnects 814, the plurality of interconnects 854, the plurality of interconnects 874 and/or the plurality of interconnects 894.

The method couples (at 940) a plurality of solder interconnects to interconnects of the substrate. In some implementations, a plurality of solder interconnects may be coupled to interconnects of the substrate 100 through openings in the solder resist layer 107 and/or openings in the solder resist layer 109.

Once the substrate (e.g., 100, 300) is provided and/or fabricated, an integrated device (e.g., 403) may be coupled to the substrate through at least a plurality of solder interconnects (e.g., 430). The substrate and the integrated device may then be coupled to a board (e.g., 401) through a plurality of solder interconnects (e.g., 420).

### Exemplary Electronic Devices

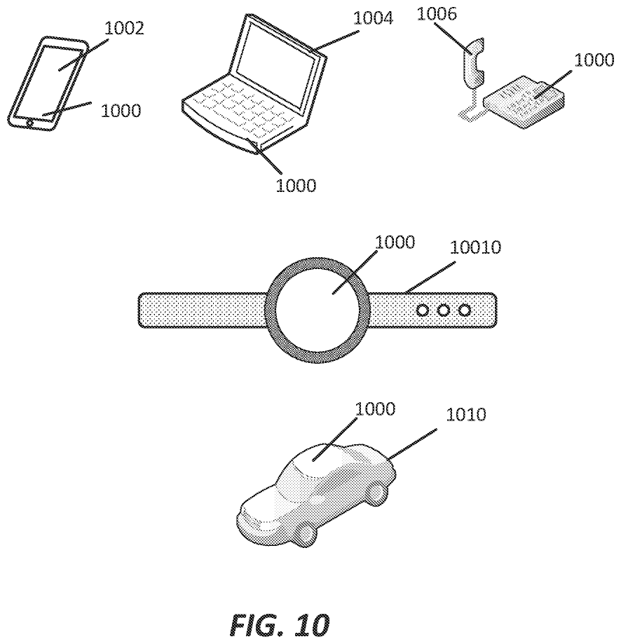

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-8C 7, 8A-8H, and/or 9-10 may be rearranged and/or combined into a single component, process, feature or function or embodied in several components, processes, or functions. Additional elements, components, processes, and/or functions may also be added without departing from the disclosure. It should also be noted FIGS. 1-5, 6A-8C 7, 8A-8H, and/or 9-10 and its corresponding description in the present disclosure is not limited to dies and/or ICs. In some implementations, FIGS. 1-5, 6A-8C 7, 8A-8H, and/or 9-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following. further examples are described to facilitate the understanding of the disclosure.

Aspect 1: A substrate comprising a core layer comprising a cavity; a region comprising a passive component block located at least partially in the cavity of the core layer, wherein the passive component block comprises a first passive device and a second passive device; at least one dielectric layer coupled to the core layer; and a plurality of interconnects located at least partially in the at least one dielectric layer.

Aspect 2: The substrate of aspect 1, wherein the first passive device comprises a first front side and a first back side, and wherein the second passive device comprises a second front side and a second back side.

Aspect 3: The substrate of aspect 2, wherein the first back side of the first passive device faces the second back side of the second passive device.

Aspect 4: The substrate of aspects 1 through 3, wherein the first passive device includes a first deep trench capacitor device, and wherein the second passive device includes a second deep trench capacitor device.

Aspect 5: The substrate of aspects 1 through 4, wherein the passive component block includes a first block core layer and a second block core layer.

Aspect 6: The substrate of aspects 1 through 5, wherein the passive component block touches the at least one dielectric layer.

Aspect 7: The substrate of aspects 1 through 6, wherein the at least one dielectric layer is located in at least part of the cavity of the core layer.

Aspect 8: The substrate of aspects 1 through 7, wherein the plurality of interconnects are configured to be electrically coupled to the passive component block.

Aspect 9: The substrate of aspects 1 through 8, wherein the at least one dielectric layer laterally surrounds the passive component block.

Aspect 10: The substrate of aspects 1 through 9, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 11: A package comprising an integrated device; and a substrate coupled to the integrated device through at least a plurality of solder interconnects. The substrate comprising a core layer comprising a cavity; a region comprising a passive component block located at least partially in the cavity of the core layer, wherein the passive component block comprises a first passive device and a second passive device; at least one dielectric layer coupled to the core layer; and a plurality of interconnects located at least partially in the at least one dielectric layer.

Aspect 12: The package of aspect 11, wherein the first passive device comprises a first front side and a first back side, and wherein the second passive device comprises a second front side and a second back side.

Aspect 13: The package of aspect 12, wherein the first back side of the first passive device faces the second back side of the second passive device.

Aspect 14: The package of aspects 11 through 13, wherein the first passive device includes a first deep trench capacitor device, and wherein the second passive device includes a second deep trench capacitor device.

Aspect 15: The package of aspects 11 through 14, wherein the passive component block includes a first block core layer and a second block core layer.

Aspect 16: The package of aspects 11 through 15, wherein the passive component block touches the at least one dielectric layer.

Aspect 17: The package of aspects 11 through 16, wherein the at least one dielectric layer is located in at least part of the cavity of the core layer.

Aspect 18: The package of aspects 11 through 17, wherein the plurality of interconnects are configured to be electrically coupled to the passive component block.

Aspect 19: The package of aspects 11 through 18, wherein the at least one dielectric layer laterally surrounds the passive component block.

Aspect 20: The package of aspects 11 through 19, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a substrate, comprising providing a core layer; forming a plurality of interconnects in the core layer and on surfaces of the core layer; forming a cavity in the core layer; providing a passive component block in the cavity of the core layer, wherein the passive component block includes a first passive device and a second passive device; forming at least one dielectric layer coupled to (i) the core layer and (ii) the passive component block; and forming a plurality of interconnects located at least partially in the at least one dielectric layer.

Aspect 22: The method of aspect 21, wherein the first passive device comprises a first front side and a first back side, and wherein the second passive device comprises a second front side and a second back side.

Aspect 23: The method of aspect 22, wherein the first back side of the first passive device faces the second back side of the second passive device.

Aspect 24: The method of aspects 21 through 23, wherein the first passive device includes a first deep trench capacitor device, and wherein the second passive device includes a second deep trench capacitor device.

Aspect 25: The method of aspects 21 through 24, wherein the passive component block includes a first block core layer and a second block core layer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A substrate comprising:
a core layer comprising a cavity;
a region comprising a passive component block located at least partially in the cavity of the core layer, wherein the passive component block comprises a first passive device and a second passive device;
at least one dielectric layer coupled to the core layer; and
a plurality of interconnects located at least partially in the at least one dielectric layer.

2. The substrate of claim 1,
wherein the first passive device comprises a first front side and a first back side, and
wherein the second passive device comprises a second front side and a second back side.

3. The substrate of claim 2, wherein the first back side of the first passive device faces the second back side of the second passive device.

4. The substrate of claim 1,
wherein the first passive device includes a first deep trench capacitor device, and
wherein the second passive device includes a second deep trench capacitor device.

5. The substrate of claim 1, wherein the passive component block includes a first block core layer and a second block core layer.

6. The substrate of claim 1, wherein the passive component block touches the at least one dielectric layer.

7. The substrate of claim 1, wherein the at least one dielectric layer is located in at least part of the cavity of the core layer.

8. The substrate of claim 1, wherein the plurality of interconnects are configured to be electrically coupled to the passive component block.

9. The substrate of claim 1, wherein the at least one dielectric layer laterally surrounds the passive component block.

10. The substrate of claim 1, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IOT) device, and a device in an automotive vehicle.

11. A package comprising:
an integrated device; and
a substrate coupled to the integrated device through at least a plurality of solder interconnects, the substrate comprising:
a core layer comprising a cavity;
a region comprising a passive component block located at least partially in the cavity of the core layer, wherein the passive component block comprises a first passive device and a second passive device;
at least one dielectric layer coupled to the core layer; and
a plurality of interconnects located at least partially in the at least one dielectric layer.

12. The package of claim 11,
wherein the first passive device comprises a first front side and a first back side, and
wherein the second passive device comprises a second front side and a second back side.

13. The package of claim 12, wherein the first back side of the first passive device faces the second back side of the second passive device.

14. The package of claim 11,
wherein the first passive device includes a first deep trench capacitor device, and
wherein the second passive device includes a second deep trench capacitor device.

15. The package of claim 11, wherein the passive component block includes a first block core layer and a second block core layer.

16. The package of claim 11, wherein the passive component block touches the at least one dielectric layer.

17. The package of claim 11, wherein the at least one dielectric layer is located in at least part of the cavity of the core layer.

18. The package of claim 11, wherein the plurality of interconnects are configured to be electrically coupled to the passive component block.

19. The package of claim 11, wherein the at least one dielectric layer laterally surrounds the passive component block.

20. The package of claim 11, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IOT) device, and a device in an automotive vehicle.

21. A method for fabricating a substrate, comprising:
providing a core layer;
forming a cavity in the core layer;
providing a passive component block in the cavity of the core layer, wherein the passive component block includes a first passive device and a second passive device;
forming at least one dielectric layer coupled to (i) the core layer and (ii) the passive component block; and
forming a plurality of interconnects located at least partially in the at least one dielectric layer.

22. The method of claim 21,
wherein the first passive device comprises a first front side and a first back side, and
wherein the second passive device comprises a second front side and a second back side.

23. The method of claim 22, wherein the first back side of the first passive device faces the second back side of the second passive device.

24. The method of claim 21,
wherein the first passive device includes a first deep trench capacitor device, and
wherein the second passive device includes a second deep trench capacitor device.

25. The method of claim 21, wherein the passive component block includes a first block core layer and a second block core layer.
